(19) United States
(12) Patent Application Publication
(10) Pub. No.: US 2025/0137124 A1
(43) Pub. Date: May 1, 2025

(54) METHOD AND DEVICE FOR DEPOSITING THIN FILM, AND THIN FILM

(71) Applicant: JIANGSU LEADMICRO NANO TECHNOLOGY CO., LTD., Wuxi (CN)

(72) Inventors: Xiang LI, Wuxi (CN); Ke MI, Wuxi (CN); Lei HU, Wuxi (CN); Jing YAO, Wuxi (CN); Min ZUO, Wuxi (CN); Angbi ZHAO, Wuxi (CN)

(21) Appl. No.: 18/834,302

(22) PCT Filed: Nov. 6, 2023
(86) PCT No.: PCT/CN2023/129919

§ 371 Date: Jul. 30, 2024

(30) Foreign Application Priority Data
Nov. 25, 2022 (CN) 202211493065.5

(51) Int. Cl. C23C 16/455; C23C 16/44

(52) U.S. Cl. CPC C23C 16/45544; C23C 16/4412

(57) ABSTRACT

The present disclosure relates to a method and apparatus for depositing a thin film, and a thin film. According to an embodiment of the present disclosure, a method for depositing a thin film includes: providing a substrate into a reaction chamber, the reaction chamber including one or more first chemical reactant outlets, and one or more second chemical reactant outlets spatially independent of the one or more first chemical reactant outlets; and making a relative displacement of the substrate to the one or more first chemical reactant outlets and the one or more second chemical reactant outlets, where at least one of a first chemical reactant passing through the first chemical reactant outlet and a second chemical reactant passing through the second chemical reactant outlet are applied to the substrate in a pulse form.

### PRIORITY CLAIM AND CROSS-REFERENCE

This application claims benefit to PCT/CN2023/129919, filed on 6 Nov. 2023, under 35 U.S.C. 365(C), which claims priority to CN Patent Appl. No. 202211493065.5, filed on 25 Nov. 2022.

### BACKGROUND OF THE DISCLOSURE

### 2. Field of the Disclosure

The present disclosure generally relates to the field of semiconductor manufacturing, and in particular to a method and apparatus for depositing a thin film, and a thin film.

### 3. Description of the Related Art

Atomic layer deposition (ALD) technology has the advantages including dense film, high uniformity and high step coverage, and thus has been widely used in the fields of semiconductors, new energy, etc. On this basis, a new technique called spatial ALD (SALD) has emerged. In an ideal spatial atomic layer deposition approach, reaction cycles are performed in an order of spatial positions, and the substrate or base is subjected to a first chemical reactant and a second chemical reactant respectively in the movement process, so that different chemical reactants or chemical sources are separated in space, thereby implementing thin film deposition by layer-by-layer stacking. Since the separation is based on space rather than time, the deposition rate is improved, so that the deposition time of the spatial atomic layer deposition can be significantly shorter than that required by reaction cycles of conventional ALD.

However, in an actual mass production line, in order to achieve the mass production performance, it is often difficult to completely separate different chemical reactants, so undesirable chemical vapor deposition (CVD) may occur near the spray holes, in the exhaust tank, or in the chemical source diffusion region and the like. Long-time operation of the machine will cause powder accumulation in the CVD region, and to a certain extent, peeling will occur, so that the accumulated powder will fall on the surface of the product, thus affecting the appearance, performance and various other aspects of the product. At present, the above problems can only be solved by lengthening the machine body or shortening the machine maintenance intervals for frequent maintenance, which leads to an increase in the cost of the machine.

In view of this, there is an urgent need in the art to provide an improved solution to solve the above problems.

### SUMMARY OF THE DISCLOSURE

In view of this, the present disclosure provides a method and apparatus for depositing a thin film, and a thin film to at least solve the above technical problems.

According to an embodiment of the present disclosure, the present disclosure provides a method for depositing a thin film, including: providing a substrate into a reaction chamber, the reaction chamber including one or more first chemical reactant outlets, and one or more second chemical reactant outlets spatially independent of the one or more first chemical reactant outlets; and making a relative displacement of the substrate to the one or more first chemical reactant outlets and the one or more second chemical reactant outlets, where at least one of a first chemical reactant passing through the first chemical reactant outlet and a second chemical reactant passing through the second chemical reactant outlet are applied to the substrate in a pulse form.

According to another embodiment of the present disclosure, the substrate includes an upper surface and a lower surface, and the one or more first chemical reactant outlets and the one or more second chemical reactant outlets are opposite to at least one of the upper surface and the lower surface of the substrate.

According to another embodiment of the present disclosure, the method for depositing a thin film further includes one or more purge outlets located between the one or more first chemical reactant outlets and the one or more second chemical reactant outlets.

According to another embodiment of the present disclosure, the method for depositing a thin film further includes applying a first inert gas to the substrate via the one or more purge outlets in a normally open manner.

According to another embodiment of the present disclosure, in the method for depositing a thin film, the first inert gas includes argon or nitrogen.

According to another embodiment of the present disclosure, the method for depositing a thin film further includes a first exhaust port located between the one or more first chemical reactant outlets and the one or more purge outlets, and a second exhaust port located between the one or more second chemical reactant outlets and the one or more purge outlets. The first exhaust port is configured to discharge the first chemical reactant out of the reaction chamber, and the second exhaust port is configured to discharge the second chemical reactant out of the reaction chamber.

According to another embodiment of the present disclosure, the first exhaust port and/or the second exhaust port include/includes a throttling device.

According to another embodiment of the present disclosure, in the method for depositing a thin film, the relative displacement includes rotation, advance or swing.

According to another embodiment of the present disclosure, in the method for depositing a thin film, the first chemical reactant and/or the second chemical reactant are/is introduced into the reaction chamber by using a second inert gas as a carrier gas.

According to another embodiment of the present disclosure, in the method for depositing a thin film, the second inert gas includes argon or nitrogen.

According to another embodiment of the present disclosure, in the method for depositing a thin film, a reaction temperature of the reaction chamber is 25° C. to 400° C.

According to another embodiment of the present disclosure, in the method for depositing a thin film, the substrate includes a flexible thin film, glass or a silicon wafer, where the flexible thin film includes polyethylene terephthalate (PET), polyethylene naphthalate (PEN) and polyimide (PI).

According to another embodiment of the present disclosure, in the method for depositing a thin film, the first chemical reactant is applied to the substrate in a pulse form, and the second chemical reactant is applied to the substrate in a normally open form.

According to another embodiment of the present disclosure, in the method for depositing a thin film, the first chemical reactant and the second chemical reactant are applied to the substrate in a gapless alternating pulse form.

According to another embodiment of the present disclosure, in the method for depositing a thin film, the first chemical reactant and the second chemical reactant are applied to the substrate in a source intersection alternating pulse form.

According to another embodiment of the present disclosure, in the method for depositing a thin film, the first chemical reactant and the second chemical reactant are applied to the substrate in a source gap alternating pulse form.

According to an embodiment of the present disclosure, the present disclosure provides an apparatus for depositing a thin film, including: one or more first chemical reactant outlets, configured to provide a first chemical reactant into a reaction chamber; one or more second chemical reactant outlets, configured to provide a second chemical reactant into the reaction chamber, the one or more second chemical reactant outlets being spatially independent of the one or more first chemical reactant outlets; a transport assembly, configured to make a relative displacement of a substrate to the one or more first chemical reactant outlets and the one or more second chemical reactant outlets; an intake control assemblies, configured to apply at least one of the first chemical reactant and the second chemical reactant to the substrate in a pulse form; and an exhaust port assembly, configured to discharge the first chemical reactant and the second chemical reactant out of the reaction chamber.

According to another embodiment of the present disclosure, the intake control assemblies include a first intake control valve and a second intake control valve. The first intake control valve controls the first chemical reactant to be applied to the substrate in a pulse form, and the second intake control valve controls the second chemical reactant to be applied to the substrate in a pulse form.

According to another embodiment of the present disclosure, the apparatus for depositing a thin film further includes one or more purge outlets located between the one or more first chemical reactant outlets and the one or more second chemical reactant outlets.

According to another embodiment of the present disclosure, the exhaust port assembly further includes: a first exhaust port, located between the one or more first chemical reactant outlets and the one or more purge outlets, and configured to discharge the first chemical reactant out of the reaction chamber; and a second exhaust port, located between the one or more second chemical reactant outlets and the one or more purge outlets, and configured to discharge the second chemical reactant out of the reaction chamber.

According to another embodiment of the present disclosure, the present disclosure further provides a thin film, formed by any one of the above apparatuses, or formed on the substrate by any one of the above methods.

It should be understood that the broad forms of the present disclosure and their respective features may be used in combination, interchangeably and/or independently, and are not used to limit reference to separate broad forms.

### BRIEF DESCRIPTION OF THE DRAWINGS

Various aspects of the present disclosure can be easily understood from the following detailed description when read in conjunction with the accompanying drawings. It should be noted that various features may not be drawn to scale. In fact, for the sake of clarity, the dimensions of various features can be arbitrarily increased or decreased.

FIG. 1 shows a method for depositing a thin film in the prior art;

FIG. 2 shows a method for depositing a thin film according to an embodiment of the present disclosure;

FIG. 3A shows a chemical reactant single pulse application form according to an embodiment of the present disclosure;

FIG. 3B shows a chemical reactant gapless alternating pulse application form according to an embodiment of the present disclosure;

FIG. 3C shows a chemical reactant source intersection alternating pulse application form according to an embodiment of the present disclosure;

FIG. 3D shows a chemical reactant source gap alternating pulse application form according to an embodiment of the present disclosure;

FIG. 4A shows a schematic cross-sectional view of an apparatus for depositing a thin film at a first time according to an embodiment of the present disclosure;

FIG. 4B shows a schematic cross-sectional view of the apparatus for depositing a thin film at a second time according to an embodiment of the present disclosure; and

FIG. 5 shows a schematic cross-sectional view of an apparatus for depositing a thin film according to another embodiment of the present disclosure.

By convention, various features illustrated in the drawings may not be drawn to scale. Therefore, for the sake of clarity, the dimensions of various features can be arbitrarily increased or decreased. The shapes of the components illustrated in the drawings are merely exemplary shapes and are not intended to limit the actual shapes of the components. In addition, for the sake of clarity, the implementations illustrated in the drawings may be simplified. Therefore, the drawings may not illustrate all of the components of a given apparatus or device or all of the steps of a method. Finally, like reference signs may be used to indicate like features throughout the specification and drawings.

### PREFERRED EMBODIMENT OF THE PRESENT DISCLOSURE

In order to better understand the spirit of the present disclosure, the present disclosure will be further described below in conjunction with some preferred embodiments of the present disclosure.

The following disclosure provides a variety of implementations or examples that can be used to realize different features of the present disclosure. Specific examples of assemblies and configurations described below are intended to simplify the present disclosure. It is to be understood that these descriptions are merely examples and are not intended to limit the present disclosure. For example, in the following description, forming a first feature on or above a second feature may include the first and second features being in direct contact with each other in some embodiments; and may also include additional assemblies being formed between the first and second features in some embodiments, such that the first and second features may not be in direct contact. Besides, the present disclosure may reuse assembly symbols and/or numerals in a plurality of embodiments. This reuse is for the purpose of brevity and clarity, and does not in itself represent the relationship between the different embodiments and/or configurations discussed.

In this specification, unless otherwise specified or limited, the relative terms such as “central”, “longitudinal”, “lateral”, “front”, “rear”, “right”, “left”, “internal”, “external”, “lower”, “higher”, “horizontal”, “vertical”, “higher than”, “lower than”, “above”, “below”, “top” and “bottom”, and their derivatives (e.g. “horizontally”, “downward” and “upward”) should be interpreted as referring to the directions described in the discussion or in the drawings. These relative terms are used for convenience only in the description and are not required to construct or operate the present disclosure in a particular direction.

Various implementations of the present disclosure will be discussed in detail below. Although specific implementations are discussed, it should be understood that these implementations are merely used for illustrative purposes. Those skilled in the related art will recognize that other components and configurations may be used without departing from the spirit and protective scope of the present disclosure. The implementation of the present disclosure may not necessarily include all components or steps in the embodiments described in the specification, and the execution order of the steps may be adjusted according to the actual application.

As described above, this application provides a method and apparatus for depositing a thin film to solve the problems of powder accumulation and peeling in the existing spatial atomic layer deposition apparatus and prepare a thin film with higher quality.

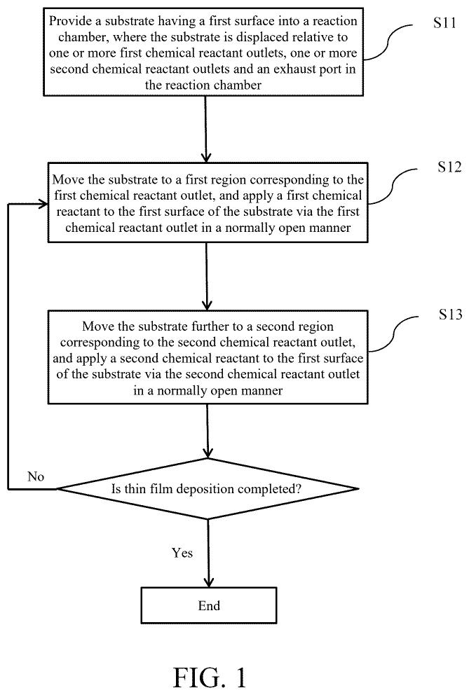

FIG. 1 shows a method for depositing a thin film in the prior art. As shown in FIG. 1, the method for depositing a thin film includes: providing a substrate having a first surface into a reaction chamber, where the substrate is displaced relative to one or more first chemical reactant outlets, one or more second chemical reactant outlets and an exhaust port in the reaction chamber (S11); moving the substrate to a first region corresponding to the first chemical reactant outlet, and applying a first chemical reactant to the first surface of the substrate via the first chemical reactant outlet in a normally open manner (S12); and moving the substrate further to a second region corresponding to the second chemical reactant outlet, and applying a second chemical reactant to the first surface of the substrate via the second chemical reactant outlet in a normally open manner (S13). After step (S13) is executed, if the thin film deposition has been completed, the operation can be ended. If the thin film deposition has not been completed, step (S12) and step (S13) may be repeated one or more times until the thin film deposition is completed and the operation is ended.

In the operation steps shown in FIG. 1, the first chemical reactant and the second chemical reactant which are different are both applied to the first surface of the substrate in a normally open manner. The normally open manner will cause not only high consumption of the chemical reactants, but also chemical vapor deposition of the two different chemical reactants near the spray holes, in the exhaust tank and in the chemical source diffusion region, thereby forming accumulated powder. When the accumulated powder peels off and drops onto the first surface of the substrate, the appearance, performance and various other aspects of the product will be adversely affected. Although the above problems can be solved by shortening the machine maintenance intervals for frequent maintenance or lengthening the machine body for more sufficient segmentation and the like, it will inevitably increase the cost of the machine and will still not help to reduce the consumption of the chemical reactants.

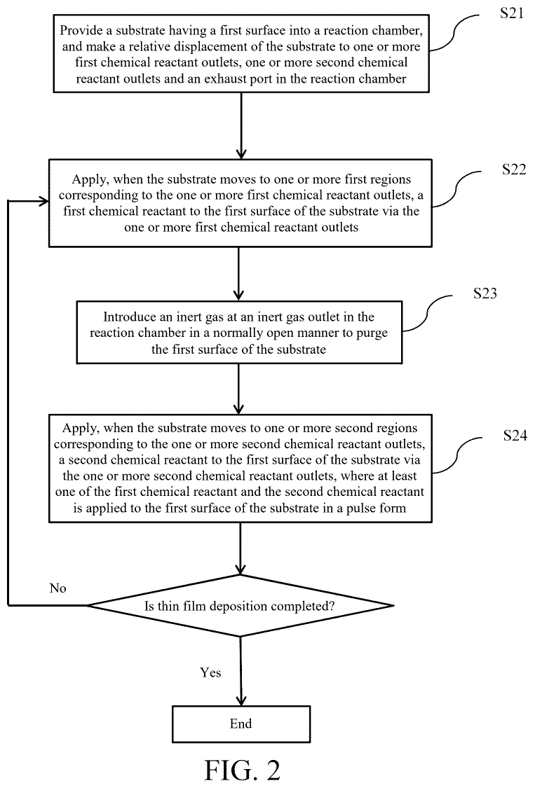

FIG. 2 shows a method for depositing a thin film according to an embodiment of the present disclosure. As shown in FIG. 2, the method for depositing a thin film includes: providing a substrate having a first surface into a reaction chamber, and making a relative displacement of the substrate to one or more first chemical reactant outlets, one or more second chemical reactant outlets and an exhaust port in the reaction chamber (S21); applying, when the substrate moves to one or more first regions corresponding to the one or more first chemical reactant outlets, a first chemical reactant to the first surface via the one or more first chemical reactant outlets (S22); introducing an inert gas at an inert gas outlet in the reaction chamber in a normally open manner to purge the first surface of the substrate (S23); and applying, when the substrate moves to one or more second regions corresponding to the one or more second chemical reactant outlets, a second chemical reactant to the first surface via the one or more second chemical reactant outlets to deposit the thin film on the first surface, where at least one of the first chemical reactant and the second chemical reactant is applied to the first surface in a pulse form (S24). In some embodiments, after step (S24) is executed, if the thin film deposition has been completed, the operation may be ended. If the thin film deposition has not been completed, step (S22) to step (S24) may be repeated one or more times until the thin film deposition is completed and the operation is ended.

In some embodiments, a total of 63 sets of first chemical reactant outlets and second chemical reactant outlets may be arranged, which may be arranged in cycles in a manner of the 1^{st} set of first chemical reactant outlet and second chemical reactant outlet, the 2^{nd} set of first chemical reactant outlet and second chemical reactant outlet, . . . , and the 63^{rd} set of first chemical reactant outlet and second chemical reactant outlet. It should be understood that the number of sets of chemical reactant outlets may not be limited to 63, and may be any number. It should still be understood that since the one or more first regions and the one or more second regions respectively correspond to the one or more first chemical reactant outlets and the one or more second chemical reactant outlets, and the one or more first chemical reactant outlets are spatially separated from the one or more second chemical reactant outlets, thus the one or more first regions are also spatially separated from the one or more second regions.

In some embodiments, the relative displacement of the substrate to the one or more first chemical reactant outlets, the one or more second chemical reactant outlets and the exhaust port may include, but not limited to, rotation, advance or swing. As an embodiment, the substrate may be any suitable silicon-containing substrate or silicon-containing base for manufacturing a semiconductor element (e.g., a photovoltaic panel) and may have any suitable shape and size. For example, the substrate may include (but not limited to) a flexible thin film, glass or a silicon wafer, and the flexible thin film may include polyethylene terephthalate (PET), polyethylene naphthalate (PEN), polyimide (PI) and other materials.

In some embodiments, the first chemical reactant and the second chemical reactant may be any suitable chemical substances for depositing a thin film, and may be selected according to the type of the thin film and the deposition method. As an embodiment, the first chemical reactant may include at least one of trimethylaluminum (Al(CH₃)₃), dimethylisopropoxyaluminum ((CH₃)₂AlOCH(CH₃)₂), aluminum trichloride (AlCl₃) or dimethylaluminum chloride (AlCl(CH₃)₂). The second chemical reactant may include at least one of oxygen (O₂), water (H₂O), ozone (O₃), hydrogen peroxide (H₂O₂) or plasma excited oxygen. As another embodiment, the first chemical reactant and/or the second chemical reactant may be introduced into the reaction chamber by using an inert gas as a carrier gas. For example, trimethylaluminum vapor may be introduced into the reaction chamber and applied to the first surface by using nitrogen as the carrier gas, and/or water vapor may be introduced into the reaction chamber and applied to the first surface by using nitrogen as the carrier gas.

In some embodiments, the one or more first chemical reactant outlets and the one or more second chemical reactant outlets may be isolated by the inert gas outlet, that is, the substrate may sequentially be moved from the first region corresponding to the first chemical reactant outlets to a purge region corresponding to the inert gas outlet, and then to the second region corresponding to the second chemical reactant outlet, thereby completing one complete deposition cycle.

In some embodiments, the exhaust port may be located at any suitable position in the reaction chamber to ensure the discharge of the reactants, and the number of the exhaust ports may not be limited to one. As an embodiment, the exhaust port may include a throttling device so as to better control the flow rate, flow velocity and other parameters related to the discharge of the chemical reactants.

In some embodiments, a reaction temperature of the reaction chamber may be set to 25° C. to 400° C., or any reaction temperature range suitable for the coating operation.

It should be understood that in the steps of the method for depositing a thin film shown in FIG. 2, the purge step (S23) is a non-reactive step, and generally, the purge step may be performed by using a gas that does not participate in the deposition reaction to remove excess reaction products and chemical reactants that have not reacted in time. For example, purging may be implemented by using N₂ or other inert gases (e.g., Ar). However, the purge step (S23) described above is not a necessary step. The reason for this is that the application of the first chemical reactant and the second chemical reactant is realized by means of the first chemical reactant outlets and the second chemical reactant outlets that are spatially separated, so that it is unnecessary to perform inert gas purging between the first chemical reactant and the second chemical reactant. Accordingly, in the reaction chamber, it is unnecessary to arrange an inert gas outlet between the first chemical reactant outlets and the second chemical reactant outlets.

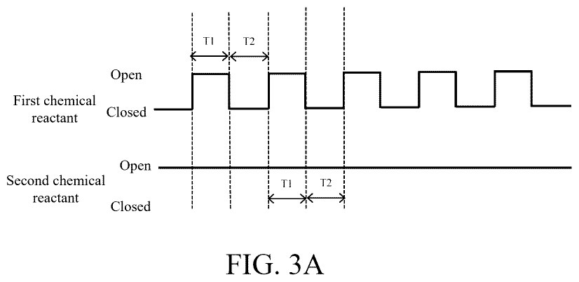

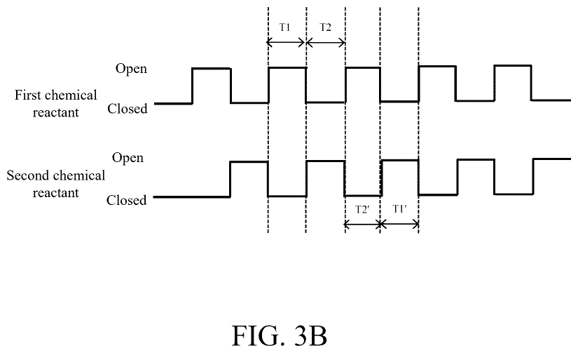

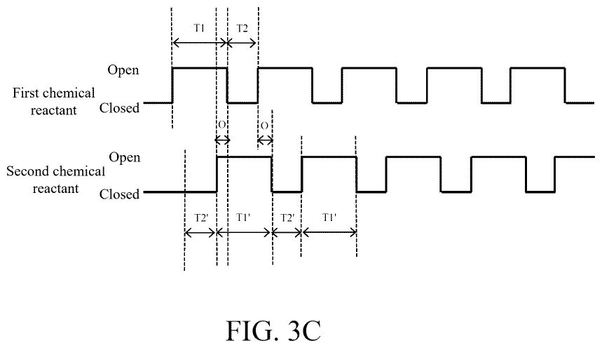

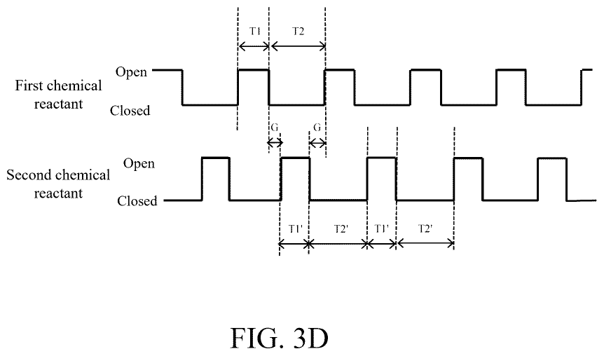

It should still be understood that the first chemical reactant and the second chemical reactant may be applied to the first surface of the substrate in various pulse forms, and the method for depositing a thin film in the present disclosure may reduce the powder accumulation and peeling and prolong the machine maintenance intervals by designing the pulse forms in step (S23) and/or step (S24), thereby reducing the cost of the machine, reducing the consumption of the chemical reactants and improving the quality of the film formed. Hereinafter, various pulse forms of the present disclosure will be described in detail with reference to FIG. 3A to FIG. 3D.

FIG. 3A shows a chemical reactant single pulse application form according to an embodiment of the present disclosure. As shown in FIG. 3A, the first chemical reactant outlet is switched between an “open” and a “closed” state, and the second chemical reactant outlet is kept in a normally “open” state, so that the first chemical reactant is applied to the first surface of the substrate in a pulse form, and the second chemical reactant is applied to the first surface of the substrate in a normally open form. It should be understood that in FIG. 3A, the pulse period T1 and the interval period T2 of the first chemical reactant may have a certain proportional relationship according to specific demands.

In an embodiment, the temperature of the reaction chamber may be set to 120° C., the reaction chamber may be set to include 63 sets of first chemical reactant outlets and second chemical reactant outlets, and the first chemical reactant and the second chemical reactant may be respectively set to trimethylaluminum vapor (as described above, nitrogen may be used as a carrier gas to carry the first chemical reactant trimethylaluminum vapor) and water vapor (as described above, nitrogen may be used as a carrier gas to carry the second chemical reactant water vapor).

In this state, the substrate (e.g., flexible PET substrate) is made to advance in the reaction chamber so as to form a relative displacement to the first chemical reactant outlets and the second chemical reactant outlets, and the first chemical reactant is introduced in a manner of a pulse period T1 of 0.5 s and an interval period T2 of 0.5 s, so that an aluminum oxide (Al₂O₃) coating can be formed on the first surface of the substrate. Specifically, in an embodiment, a first deposition target region of the substrate stays in the first region corresponding to the first chemical reactant outlet for a T1+T2 period. Then, the first deposition target region is displaced from the first region to the second region corresponding to the second chemical reactant outlet for a T1+T2 period. Compared with the case where the first chemical reactant and the second chemical reactant are both normally open in the prior art, the foregoing embodiment at least partially reduces the time that the first chemical reactant and the second chemical reactant contact each other and undergo chemical vapor deposition near the spray holes, in the exhaust pipe and/or in the chemical source diffusion region, and can reduce the consumption of the first chemical reactant by one half and reduce the powder accumulation near the spray holes, in the exhaust pipe and/or in the chemical source diffusion region.

After the coating is completed, the thickness of the Al₂O₃ coating may be further measured at multiple points. For example, on the one hand, the coating may be performed in a double-source normally open (i.e., the first chemical reactant and the second chemical reactant are both normally open) form which is common in the prior art, and after the coating is completed, the thicknesses of the coating at 10 positions and the average thickness may be obtained. On the other hand, the coating may be performed in a single pulse (i.e., only the first chemical reactant is supplied in pulses) form shown in FIG. 3A of the present disclosure, and after the coating is completed, the thicknesses of the coating at 10 substantially identical positions and the average thickness may be obtained.

Table 1 below shows a data comparison result of thicknesses of the coatings obtained in a conventional double-source normally open coating manner and a single pulse coating manner.

TABLE 1

| | Position | Position | Position | Position | Position | Position | Position | Position | Position | Position | Average |
|---|---|---|---|---|---|---|---|---|---|---|---|
| | 1 | 2 | 3 | 4 | 5 | 6 | 7 | 8 | 9 | 10 | thickness |
| Manner | (nm) | (nm) | (nm) | (nm) | (nm) | (nm) | (nm) | (nm) | (nm) | (nm) | (nm) |
| Conventional | 51.18 | 55.47 | 54.35 | 62.53 | 59.28 | 59.8 | 64.87 | 56.9 | 59.52 | 63.39 | 58.73 |
| double- | | | | | | | | | | | |
| source | | | | | | | | | | | |
| normally | | | | | | | | | | | |
| open | | | | | | | | | | | |
| First | 53.43 | 54.98 | 61.76 | 52.89 | 69.44 | 54.97 | 45.71 | 55.41 | 61.72 | 46.99 | 55.73 |
| chemical | | | | | | | | | | | |
| reactant | | | | | | | | | | | |
| pulse | | | | | | | | | | | |

When the 0.5 s-0.5 s single pulse manner is used to perform the coating, the consumption of the first chemical reactant and the powder accumulation can be reduced by one half under the condition that the thickness (e.g., the average thickness) of the coating is basically unchanged.

FIG. 3B shows a chemical reactant gapless alternating pulse application form according to an embodiment of the present disclosure. Different from the chemical reactant single pulse application form shown in FIG. 3A, the first chemical reactant and the second chemical reactant in FIG. 3B are both applied to the first surface of the substrate in a pulse form. Accordingly, the first chemical reactant outlet and the second chemical reactant outlet are both switched between an “open” and a “closed” state.

As shown in FIG. 3B, the pulse period T1 of the first chemical reactant is equal to the interval period T2′ of the second chemical reactant, and the interval period T2 of the first chemical reactant is equal to the pulse period T1′ of the second chemical reactant. In this manner, pulse edges of the first chemical reactant and the second chemical reactant are all aligned, so that the first chemical reactant and the second chemical reactant can be applied to the first surface of the substrate in a gapless alternating pulse form.

It should be understood that in FIG. 3B, the pulse period T1 and the interval period T2 of the first chemical reactant may have a certain proportional relationship according to specific demands, and the pulse period T1′ and the interval period T2′ of the second chemical reactant may also have a certain proportional relationship according to specific demands, as long as the pulse edges of the two chemical reactants are aligned.

In an embodiment, the temperature of the reaction chamber may be set to 250° C., the reaction chamber may be set to include 21 sets of first chemical reactant outlets and second chemical reactant outlets, and the first chemical reactant and the second chemical reactant may be respectively set to diethylzinc vapor and water vapor.

In this state, the substrate (e.g., glass substrate) is made to advance in the reaction chamber so as to form a relative displacement to the first chemical reactant outlets and the second chemical reactant outlets, the first chemical reactant is introduced in a manner of a pulse period T1 of 0.5 s and an interval period T2 of 0.5 s, and the second chemical reactant is introduced in a manner of an interval period T2′ of 0.5 s and a pulse period T1′ of 0.5 s so that a zinc oxide (ZnO) coating can be formed on the first surface of the substrate. Specifically, in an embodiment, a first deposition target region of the substrate stays in the first region corresponding to the first chemical reactant outlet for a T1+T2 period. Then, the first deposition target region is displaced from the first region to the second region corresponding to the second chemical reactant outlet for a T2′+T1′ period. Compared with the case where the first chemical reactant and the second chemical reactant are both normally open in the prior art, the foregoing embodiment at least partially reduces the time that the first chemical reactant and the second chemical reactant contact each other and undergo chemical vapor deposition near the spray holes, in the exhaust pipe and/or in the chemical source diffusion region, and can reduce the consumptions of the first chemical reactant and the second chemical reactant by one half and reduce the powder accumulation near the spray holes, in the exhaust pipe and/or in the chemical source diffusion region.

After the coating is completed, the thickness of the ZnO coating may be further measured at multiple points. For example, on the one hand, the coating may be performed in a double-source normally open (i.e., the first chemical reactant and the second chemical reactant are both normally open) form which is common in the prior art, and after the coating is completed, the thicknesses of the coating at 10 positions and the average thickness may be obtained. On the other hand, the coating may be performed in a gapless alternating pulse form shown in FIG. 3B of the present disclosure, and after the coating is completed, the thicknesses of the coating at 10 substantially identical positions and the average thickness may be obtained.

Table 2 below shows a data comparison result of thicknesses of the coatings obtained in a conventional double-source normally open coating manner and a gapless alternating pulse coating manner.

TABLE 2

| | Position | Position | Position | Position | Position | Position | Position | Position | Position | Position | Average |
|---|---|---|---|---|---|---|---|---|---|---|---|
| | 1 | 2 | 3 | 4 | 5 | 6 | 7 | 8 | 9 | 10 | thickness |
| Manner | (nm) | (nm) | (nm) | (nm) | (nm) | (nm) | (nm) | (nm) | (nm) | (nm) | (nm) |
| Conventional | 19.424 | 20.972 | 23.708 | 22.408 | 19.44 | 21.052 | 25.508 | 23.772 | 22.056 | 20.492 | 21.88 |
| double- | | | | | | | | | | | |
| source | | | | | | | | | | | |
| normally | | | | | | | | | | | |
| open | | | | | | | | | | | |
| Gapless | 17.144 | 19.288 | 18.696 | 20.404 | 20.64 | 21.512 | 23.256 | 20.248 | 21.292 | 21.3 | 20.38 |
| alternating | | | | | | | | | | | |
| pulse | | | | | | | | | | | |

When the 0.5 s-0.5 s gapless alternating pulse manner is used to perform the coating, the consumptions of the first chemical reactant and the second chemical reactant can be reduced by one half, and the powder accumulation can be reduced by ¾ under the condition that the thickness (e.g., the average thickness) of the coating is basically unchanged.

FIG. 3C shows a chemical reactant source intersection alternating pulse application form according to an embodiment of the present disclosure. Different from the chemical reactant gapless alternating pulse application form shown in FIG. 3B, although the first chemical reactant and the second chemical reactant in FIG. 3C are still both applied to the first surface of the substrate in a pulse form, the pulse period T1 of the first chemical reactant and the pulse period T1′ of the second chemical reactant have an intersection O, which is thus called a reactant source intersection alternating pulse form.

In this manner, the first chemical reactant and the second chemical reactant can be applied to the first surface of the substrate in a chemical reactant source intersection alternating pulse form.

It should be understood that in FIG. 3C, the pulse period T1 and the interval period T2 of the first chemical reactant may have a certain proportional relationship according to specific demands, and the pulse period T1′ and the interval period T2′ of the second chemical reactant may also have a certain proportional relationship according to specific demands, as long as the pulse periods of the two chemical reactants have an intersection.

In this state, the substrate (e.g., silicon wafer) is made to advance in the reaction chamber so as to form a relative displacement to the first chemical reactant outlets and the second chemical reactant outlets, the first chemical reactant is introduced in a manner of a pulse period T1 and an interval period T2, and the second chemical reactant is introduced in a manner of an interval period T2′ and a pulse period T1′, so that a coating can be formed on the first surface of the substrate. Specifically, in an embodiment, a first deposition target region of the substrate stays in the first region corresponding to the first chemical reactant outlet for a T1+T2 period. Then, the first deposition target region is displaced from the first region to the second region corresponding to the second chemical reactant outlet for a T2′+T1′ period. Compared with the case where the first chemical reactant and the second chemical reactant are both normally open in the prior art, the foregoing embodiment at least partially reduces the time that the first chemical reactant and the second chemical reactant contact each other and undergo chemical vapor deposition near the spray holes, in the exhaust pipe and/or in the chemical source diffusion region, and can reduce the consumptions of the first chemical reactant and the second chemical reactant by one half and reduce the powder accumulation near the spray holes, in the exhaust pipe and/or in the chemical source diffusion region.

FIG. 3D shows a chemical reactant source gap alternating pulse application form according to an embodiment of the present disclosure. Different from the chemical reactant intersection alternating pulse application form shown in FIG. 3C, although the first chemical reactant and the second chemical reactant in FIG. 3D are still both applied to the first surface of the substrate in a pulse form, the pulse period T1 of the first chemical reactant and the pulse period T1′ of the second chemical reactant do not have an intersection, but have a gap G, which is thus called a reactant source gap alternating pulse form. In this case, the first chemical reactant and the second chemical reactant can be applied to the first surface of the substrate in a chemical reactant source gap alternating pulse form.

It should be understood that in FIG. 3D, the pulse period T1 and the interval period T2 of the first chemical reactant may have a certain proportional relationship according to specific demands, and the pulse period T1′ and the interval period T2′ of the second chemical reactant may also have a certain proportional relationship according to specific demands, as long as the pulse periods of the two chemical reactants have a gap.

In this state, the substrate (e.g., semiconductor wafer) is made to advance in the reaction chamber so as to form a relative displacement to the first chemical reactant outlets and the second chemical reactant outlets, the first chemical reactant is introduced in a manner of a pulse period T1 and an interval period T2, and the second chemical reactant is introduced in a manner of a pulse period T1′ and an interval period T2′, so that a coating can be formed on the first surface of the substrate. Specifically, in an embodiment, a first deposition target region of the substrate stays in the first region corresponding to the first chemical reactant outlet for a T1+T2 period. Then, the first deposition target region is displaced from the first region to the second region corresponding to the second chemical reactant outlet for a T1′+T2′ period. Compared with the case where the first chemical reactant and the second chemical reactant are both normally open in the prior art, the foregoing embodiment at least partially reduces the time that the first chemical reactant and the second chemical reactant contact each other and undergo chemical vapor deposition near the spray holes, in the exhaust pipe and/or in the chemical source diffusion region, and can reduce the consumptions of the first chemical reactant and the second chemical reactant and reduce the powder accumulation near the spray holes, in the exhaust pipe and/or in the chemical source diffusion region.

In this manner, gas may be exhausted by using the same one exhaust system. Since the two reactants are both introduced in a pulse manner and are staggered with each other, there is no need to arrange different exhaust pipes or add purge gas between the reactant outlets, i.e., no purge outlet is arranged between different reactant outlets and the same one exhaust pipe is adopted, which can ensure the reduction in the powder accumulation along with simplifying the apparatus, reducing the apparatus volume and lowering the cost, thereby prolonging the maintenance intervals.

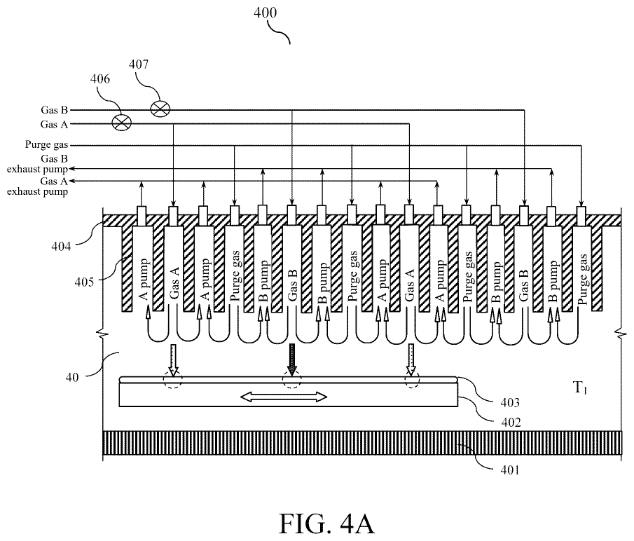

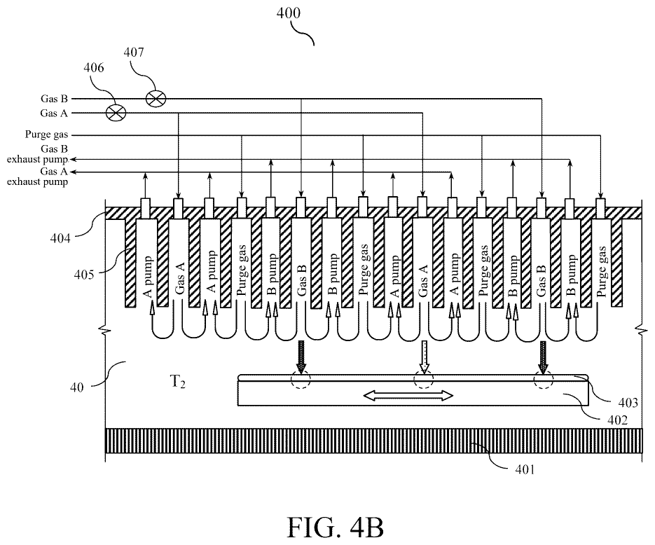

FIG. 4A shows a schematic cross-sectional view of an apparatus for depositing a thin film at a first time according to an embodiment of the present disclosure. As shown in FIG. 4A, the apparatus for depositing a thin film (400) includes a plurality of gas ports (405) located in a cover plate (404), which have first chemical reactant outlets and second chemical reactant outlets spatially independent of each other, wherein the first chemical reactant outlets may be configured to provide a first chemical reactant (gas A) into a reaction chamber (40) of the apparatus for depositing a thin film (400), and the second chemical reactant outlets may be configured to provide a second chemical reactant (gas B) into the reaction chamber (40). Two sides of each first chemical reactant outlet have exhaust ports (A pumps), which may discharge the excess gas A in the reaction chamber (40) under the action of a gas A exhaust pump located outside the reaction chamber (40). Similarly, two sides of each second chemical reactant outlet have exhaust ports (B pumps), which may discharge the excess gas B in the reaction chamber (40) under the action of a gas B exhaust pump located outside the reaction chamber (40). It should be understood that the apparatus for depositing a thin film (400) may further includes a pedestal (401).

In an embodiment, the first chemical reactant outlets and the second chemical reactant outlets may receive the first chemical reactant (gas A) and the second chemical reactant (gas B) from the outside of the reaction chamber (40) under the control of intake control assemblies (406, 407). In this manner, the intake control assemblies (406, 407) may control at least one of the first chemical reactant and the second chemical reactant to be applied to a substrate (403) in pulse forms described in FIG. 2 to FIG. 3D above. As an embodiment, the first intake control valve (406) may be used to control the first chemical reactant to be applied to the substrate in a pulse form, and the second intake control valve (407) may control the second chemical reactant to be applied to the substrate in a pulse form. It should be understood that the intake control assemblies are not limited to the first intake control valve (406) and the second intake control valve (407), and any suitable assemblies may be used to control the delivery of the chemical reactants.

In another embodiment, a purge outlet may be further arranged between the first chemical reactant outlet and the second chemical reactant outlet. The purge outlet may receive a purge gas (e.g., an inert gas such as argon or nitrogen) from the outside of the reaction chamber (40), and apply the purge gas to the substrate (403) in a normally open manner so as to purge the surface of the substrate (403). In this case, a first exhaust port is located between the first chemical reactant outlet and the purge outlet, and a second exhaust port is located between the second chemical reactant outlet and the purge outlet. However, it should be understood that the apparatus for depositing a thin film (400) may not necessarily include the purge outlet, so the first exhaust port and the second exhaust port may be combined into the same one exhaust port such that the excess gas A and the excess gas B in the reaction chamber (40) are discharged through the same exhaust port assembly.

Further, the apparatus for depositing a thin film (400) further includes a transport assembly (402), which may move along a track or any suitable moving mechanism. The transport assembly (402) may, for example (but not limited to), reciprocate horizontally in the reaction chamber (40) along a linear path (as shown by the double-headed arrow in FIG. 4A). In this manner, the transport assembly (402) may carry the substrate (403) and drive the substrate (403) to reciprocate horizontally in the reaction chamber (40) of the apparatus for depositing a thin film (400), so that the substrate (403) is displaced relative to the first chemical reactant outlets and the second chemical reactant outlets. It should be understood that the substrate (403) may be, for example, an element to be processed, such as a chip or a wafer. Besides, the substrate (403) may be an independent substrate, or a continuous substrate (for example, but not limited to, a flexible substrate and a roll-to-roll substrate), and thus, can be flexibly used in the apparatus for depositing a thin film (400). Those skilled in the art should understand that the substrate (403) may be either a bare substrate or a substrate with one or more films or features deposited. Besides, the substrate (403) may be, for example, one or more of silicon, silicon germanium, gallium arsenide, gallium nitride, germanium, gallium phosphide, indium phosphide, sapphire or silicon carbide.

FIG. 4A shows a transient position of the substrate (403) moving horizontally from left to right relative to the first chemical reactant outlet and the second chemical reactant outlet to time T1. At time T1, the first chemical reactant (gas A), the second chemical reactant (gas B) and the first chemical reactant (gas A) (as shown by three down arrows in FIG. 4A) are respectively deposited on three positions (as shown by three dashed boxes in FIG. 4A) on the upper surface of the substrate (403) from left to right at the same time. With the relative displacement of the substrate (403), different reactants can be deposited on the substrate (403), as described below.

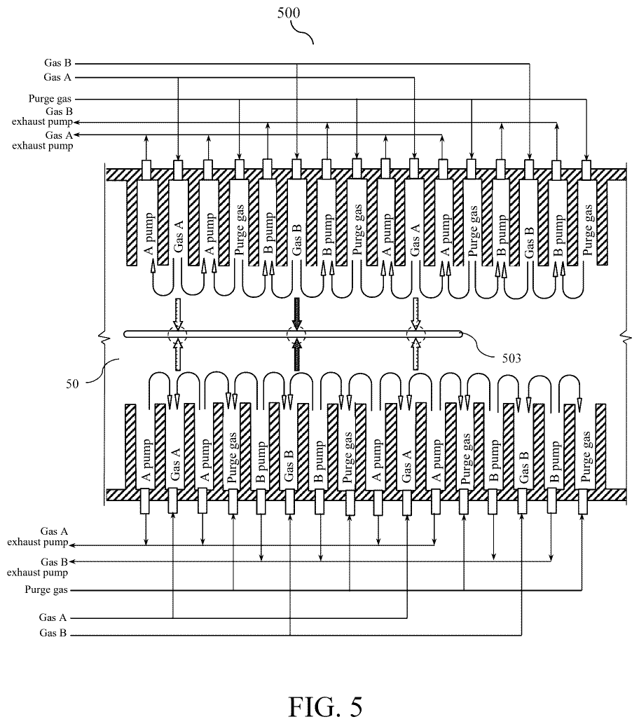

FIG. 4B shows a schematic cross-sectional view of the apparatus for depositing a thin film at a second time according to an embodiment of the present disclosure. The apparatus for depositing a thin film in FIG. 4B has the same structure as the apparatus for depositing a thin film shown in FIG. 4A. The difference is that FIG. 4B shows a transient position of the substrate (403) further moving horizontally to the right relative to the first chemical reactant outlet and the second chemical reactant outlet to time T₂. At time T₂, the second chemical reactant (gas B), the first chemical reactant (gas A) and the second chemical reactant (gas B) (as shown by three down arrows in FIG. 4B) are respectively deposited on three positions (as shown by three dashed boxes in FIG. 4B, in one-to-one correspondence to the three dashed boxes in FIG. 4A) on the upper surface of the substrate (403) from left to right at the same time. In this manner, as the substrate (403) moves from time T₁ to time T₂, the spatial atomic layer deposition of different chemical reactants (e.g., gas A and gas B) can be implemented at three positions on the upper surface of the substrate (403). It should be understood that the above three positions are merely embodiments, and actually, there may be any number of different positions or regions; and the numbers of the first chemical reactant outlets and the second chemical reactant outlets are not limited to those shown in FIG. 4A and FIG. 4B, and may be any required number. FIG. 5 shows a schematic cross-sectional view of an apparatus for depositing a thin film according to another embodiment of the present disclosure. Different from the apparatus for depositing a thin film shown in FIG. 4A and FIG. 4B, in the apparatus for depositing a thin film (500) shown in FIG. 5, there are the first chemical reactant outlets and the second chemical reactant outlets spatially independent of each other on both the upper part and the lower part of the reaction chamber (50), and the first chemical reactant outlets and the second chemical reactant outlets on the upper part may preferably correspond to the first chemical reactant outlets and the second chemical reactant outlets on the lower part. The substrate (503) may be displaced (e.g., reciprocate horizontally or move in one direction) relative to the first chemical reactant outlets and the second chemical reactant outlets in the reaction chamber (50) along a linear path. In this manner, the apparatus for depositing a thin film (500) shown in FIG. 5 can perform the spatial atomic layer deposition on both the upper surface and the lower surface of the substrate (503), thereby further improving the process efficiency.

The first chemical reactant outlets, the second chemical reactant outlets and the exhaust ports in the apparatus for depositing a thin film may be movably arranged in the chamber, and relative positions of the first chemical reactant outlets, the second chemical reactant outlets and the exhaust ports may be adjusted through a moving device. The first chemical reactant outlets, the second chemical reactant outlets and the exhaust ports may be respectively arranged through independent mechanical structures, and a plurality of different types of outlets and exhaust ports may be arranged independently and adjusted separately. By adjusting the sizes of the first region and the second region, the durations of the substrate linearly moving through the first region and the second region can be adjusted, thereby satisfying different process requirements for reactions and gas contact durations under the condition of different reactants. With the throttling devices, gas pressures of the first region and the second region can be adjusted at the same time.

In the case that the substrate moves linearly, when a position of the substrate passes through the first region and the second region, as the reactants are introduced in a pulse manner, this position of the substrate undergoes two or more pulses in the first region and the second region, which can ensure the completeness of ALD half-reaction; and the introduction of the reactant gasses in a pulse manner can reduce the contact between the two reaction sources, thereby reducing the probability and quantity of dust generated, and shortening the maintenance time of the apparatus while ensuring the quality.

Therefore, the apparatuses for depositing a thin film shown in FIG. 4A to FIG. 5 can deposit a thin film on the upper surface and/or the lower surface of the substrate by the methods described in FIG. 2 to FIG. 3D (i.e., applying at least one of the first chemical reactant and the second chemical reactant to the substrate in a pulse form). The method for depositing a thin film provided in the present disclosure can reduce the probability of chemical vapor deposition of two different chemical reactants in unit time, prolong the time for forming serious powder accumulation, and prolong the maintenance intervals (avoid frequent maintenance) along with ensuring the process effects, thereby reducing the apparatus cost.

Besides, the method for depositing a thin film provided in the present disclosure can significantly reduce the consumptions of the chemical reactants for implementing coating, thereby improving the utilization rates of the chemical reactants and further reducing the apparatus cost.

The present disclosure further provides an apparatus for depositing a thin film, which can deposit a thin film on a substrate by performing the method for depositing a thin film of the present disclosure. The apparatus for depositing a thin film of the present disclosure can effectively reduce powder accumulation and peeling and prolong the machine maintenance intervals, thereby reducing the cost of the machine, reducing the consumptions of the chemical reactants and forming a high-quality thin film.

It should be understood that the apparatus for depositing a thin film of the present disclosure is any suitable apparatus that can perform the method for depositing a thin film of the present disclosure. In some embodiments, the apparatus for depositing a thin film of the present disclosure may be a chemical vapor deposition apparatus or an apparatus based on the working principle of chemical vapor deposition. In some embodiments, the apparatus for depositing a thin film of the present disclosure may be a plasma chemical vapor deposition apparatus, and the plasma in the plasma chemical vapor deposition apparatus can reduce the surface binding energy of chemical reactants, thereby promoting the formation of the thin film. It should still be understood that the apparatus for depositing a thin film of the present disclosure can deposit a thin film on a silicon substrate in a batch manner to further increase the production capacity.

The present disclosure further provides a thin film, which may be formed by the apparatus for depositing a thin film of the present disclosure. The present disclosure further provides a thin film, which may be formed on a substrate by the method for depositing a thin film of the present disclosure. The thin film of the present disclosure has the advantages of few defects, high uniformity, high quality, etc.

The description in this specification is provided such that any person skilled in the art can perform or use the present disclosure. Various modifications to the present disclosure will be readily apparent to those skilled in the art, and the general principles defined in this specification can be applied to other variations without departing from the spirit or scope of the present disclosure. Therefore, the present disclosure is not limited to the examples and designs described in this specification, but is given the widest scope consistent with the principles and novel features disclosed in this specification.

The technical contents and technical features of the present disclosure have been described by the above related embodiments, but the above embodiments are merely examples for implementing the present disclosure. Those skilled in the art can make various substitutions and modifications based on the teaching and disclosure of this disclosure without departing from the spirit of the present disclosure. Therefore, the disclosed embodiments of the present disclosure do not limit the scope of the present disclosure. On the contrary, modifications and equivalent arrangements included in the spirit and scope of the claims are all included in the scope of the present disclosure.

1. A method for depositing a thin film, comprising:
providing a substrate into a reaction chamber, the reaction chamber comprising one or more first chemical reactant outlets, and one or more second chemical reactant outlets spatially independent of the one or more first chemical reactant outlets; and
making a relative displacement of the substrate to the one or more first chemical reactant outlets and the one or more second chemical reactant outlets, wherein at least one of a first chemical reactant passing through the first chemical reactant outlet and a second chemical reactant passing through the second chemical reactant outlet are applied to the substrate in a pulse form.

2. The method according to claim 1, wherein the substrate comprises an upper surface and a lower surface, and the one or more first chemical reactant outlets and the one or more second chemical reactant outlets are opposite to at least one of the upper surface and the lower surface of the substrate.

3. The method according to claim 1, further comprising one or more purge outlets located between the one or more first chemical reactant outlets and the one or more second chemical reactant outlets.

4. The method according to claim 3, further comprising applying a first inert gas to the substrate via the one or more purge outlets in a normally open manner.

5. The method according to claim 4, wherein the first inert gas comprises argon or nitrogen.

6. The method according to claim 3, further comprising a first exhaust port located between the one or more first chemical reactant outlets and the one or more purge outlets, and a second exhaust port located between the one or more second chemical reactant outlets and the one or more purge outlets, wherein the first exhaust port is configured to discharge the first chemical reactant out of the reaction chamber, and the second exhaust port is configured to discharge the second chemical reactant out of the reaction chamber.

7. The method according to claim 6, wherein the first exhaust port and/or the second exhaust port comprise/comprises a throttling device.

8. The method according to claim 1, wherein the relative displacement comprises rotation, advance or swing.

9. The method according to claim 1, wherein the first chemical reactant and/or the second chemical reactant are/is introduced into the reaction chamber by using a second inert gas as a carrier gas.

10. The method according to claim 9, wherein the second inert gas comprises argon or nitrogen.

11. The method according to claim 1, wherein a reaction temperature of the reaction chamber is 25° C. to 400° C.

12. The method according to claim 1, wherein the substrate comprises a flexible thin film, glass or a silicon wafer, wherein the flexible thin film comprises polyethylene terephthalate (PET), polyethylene naphthalate (PEN) and polyimide (PI).

13. The method according to any one of claims 1 to 12, wherein the first chemical reactant is applied to the substrate in a pulse form, and the second chemical reactant is applied to the substrate in a normally open form.

14. The method according to any one of claims 1 to 12, wherein the first chemical reactant and the second chemical reactant are applied to the substrate in a gapless alternating pulse form.

15. The method according to any one of claims 1 to 12, wherein the first chemical reactant and the second chemical reactant are applied to the substrate in a source intersection alternating pulse form.

16. The method according to any one of claims 1 to 12, wherein the first chemical reactant and the second chemical reactant are applied to the substrate in a source gap alternating pulse form.

17. An apparatus for depositing a thin film, comprising:
one or more first chemical reactant outlets, configured to provide a first chemical reactant into a reaction chamber;
one or more second chemical reactant outlets, configured to provide a second chemical reactant into the reaction chamber, the one or more second chemical reactant outlets being spatially independent of the one or more first chemical reactant outlets;
a transport assembly, configured to make a relative displacement of a substrate to the one or more first chemical reactant outlets and the one or more second chemical reactant outlets;
intake control assemblies, configured to apply at least one of the first chemical reactant and the second chemical reactant to the substrate in a pulse form; and
an exhaust port assembly, configured to discharge the first chemical reactant and the second chemical reactant out of the reaction chamber.

18. The apparatus for depositing a thin film according to claim 17, wherein the intake control assemblies comprise a first intake control valve and a second intake control valve, the first intake control valve controlling the first chemical reactant to be applied to the substrate in a pulse form, and the second intake control valve controlling the second chemical reactant to be applied to the substrate in a pulse form.

19. The apparatus for depositing a thin film according to claim 17, further comprising one or more purge outlets located between the one or more first chemical reactant outlets and the one or more second chemical reactant outlets.

20. The apparatus for depositing a thin film according to claim 19, wherein the exhaust port assembly further comprises:
a first exhaust port, located between the one or more first chemical reactant outlets and the one or more purge outlets, and configured to discharge the first chemical reactant out of the reaction chamber; and
a second exhaust port, located between the one or more second chemical reactant outlets and the one or more purge outlets, and configured to discharge the second chemical reactant out of the reaction chamber.

21. A thin film, formed by the apparatus for depositing a thin film according to any one of claims 17 to 20.

22. A thin film formed on the substrate by the method according to any one of claims 1 to 12.
